(19) United States
(12) Patent Application Publication
(10) Pub. No.: US 2015/0107769 A1
(43) Pub. Date: Apr. 23, 2015

(54) HARD MASK AND METHOD OF MANUFACTURING THE SAME

(71) Applicant: ULVAC, INC, Chigasaki-shi, Kanagawa (JP)

(72) Inventor: Katsuaki Nakano, Susono-shi (JP)

(73) Assignee: ULVAC, INC., Chigasaki-shi, Kanagawa (JP)

(21) Appl. No.: 14/397,975

(22) PCT Filed: May 10, 2013
(86) PCT No.: PCT/JP2013/003012

§ 371 Date: Oct. 30, 2014

(30) Foreign Application Priority Data
Jun. 22, 2012 (JP) 2012-141440

(51) Int. Cl. H01L 21/033; C23C 14/06; C23C 14/00

(52) U.S. Cl. CPC H01L 21/0337; C23C 14/0036; C23C 14/0641; H01L 21/0332; H01L 21/0335
USPC 156/345.3; 204/192.15

(57) ABSTRACT

A hard mask is provided which, while having a film density to demonstrate etching resistance, is low in film stress. The hard mask HD of this invention, which is provided to restrict the range of processing to the surface of a to-be-processed object W at the time of performing a predetermined processing to the to-be-processed object, is constituted by a titanium nitride film. This titanium nitride film is made into a two-layer structure. A lower-side layer L1 has a film thickness h1 within a range of 5 to 50% of the total film thickness ht of the hard mask, and also has a film density within a range of 3.5 to 4.7 g/cm³. An upper-side layer has a film density within a range of 4.8 to 5.3 g/cm³.

The present invention relates to a hard mask and a method of manufacturing a hard mask and, in particular, to the hard mask which is used to restrict the range of processing to an object to be processed (hereinafter also referred to as a “to-be-processed object”) in the manufacturing step of a semiconductor device.

### BACKGROUND ART

When dry-etching an interlayer dielectric film as a to-be-processed object in order to obtain a predetermined wiring pattern in the manufacturing step of a semiconductor device, this kind of hard mask is used to restrict the range of etching. As this kind of hard mask, there is generally known one which is made up of a single layer such as titanium nitride film, titanium film, tantalum film, or tantalum nitride film (see, for example, Patent Document 1). Since the hard mask for this kind of use is said to require etching resistance (etching durability), the film density shall preferably be high. On the other hand, if the film stress is high, when the interlayer dielectric film is subjected to dry etching, the etching shape changes overall or locally and, consequently, the wiring pattern changes. Therefore, the film stress shall preferably be as low as possible.

The film to constitute the above-described hard mask is ordinarily deposited, e.g., taking mass-productivity into consideration, by using a target made of titanium or tantalum, and by sputtering (or by reactive sputtering) in which nitrogen gas is introduced depending on necessity. However, explanation is made, e.g., of an example in which a titanium nitride film is deposited by reactive sputtering. If the sputtering conditions (electric power to be applied, the amount of nitrogen gas to be introduced, the evacuation speed, and the like) are set so that the titanium nitride film has such a degree of film density as will demonstrate etching resistance, the film stress will be in the order of 1000 MPa. On the other hand, if the sputtering conditions (electric power to be applied, the amount of nitrogen gas to be introduced, the evacuation speed, and the like) are set such that the film stress of the titanium nitride film attains a low stress, e.g., in excess of −100 MPa, there cannot be obtained such a film density as will demonstrate etching resistance.

In other words, as shown in FIG. 3, in the titanium nitride film in which the film has been formed by the reactive sputtering, there is a relationship between the film stress and the film density in that the lower becomes the film stress, the lower also becomes the film density substantially in proportion thereto. This is considered to be due to the physical characteristics of the titanium nitride film. Therefore, it has been said to be impossible to form by reactive sputtering a titanium nitride film which is low in film stress while having a film density demonstrating etching resistance. Under the circumstances, after every effort, the inventor of this invention has obtained a finding that it is possible to obtain a titanium nitride film having a film density that can demonstrate etching resistance with low film stress, if the hard mask is deposited by titanium nitride in a two-layer structure made up of: a lower-side layer of titanium nitride which is relatively low in film density and which is also low in film stress; and an upper-side layer which is relatively high in film density and which is also high in film stress.

### PRIOR ART DOCUMENTS

### Patent Documents

Patent Document 1: Japanese Patent Application Publication No. 2011-61041

### SUMMARY OF THE INVENTION

### Problems to be Solved by the Invention

In view of the above points, this invention has a problem of providing a hard mask and a method of manufacturing a hard mask which has a film density to demonstrate the etching resistance and whose film stress is low.

### Means of Solving the Problems

To solve the above-described problems, the hard mask of this invention is provided to restrict a range of processing to a surface of a to-be-processed object when a predetermined processing is performed on the to-be-processed object. The hard mask is constituted by a titanium nitride film and is made into a two-layer structure with: a lower-side layer having a film thickness within a range of 5 to 50% of a total film thickness of the hard mask and also having a film density within a range of 3.5 to 4.7 g/cm³; and an upper-side layer having a film density within a range of 4.8 to 5.3 g/cm³.

According to this arrangement, the to-be-processed object is first provided with the lower-side layer which is constituted by titanium nitride and which has a film density within a range of 3.5 to 4.7 g/cm³. Therefore, due to titanium atoms or nitrogen atoms which are present at relatively stable interatomic distances to the lower-side layer, the film stress will become close to zero. Then, on the surface of this lower-side layer, there is provided the upper-side layer which has a film density within a range of 4.8 to 5.3 g/cm³. The upper-side layer is narrower in the interatomic distances of titanium atoms and nitrogen atoms and the film stress is high. However, since the upper-side layer is formed on the surface of the lower-side layer, when the interatomic distances in the upper-side layer have extended so as to be of appropriate distances, the lower-side layer will absorb the elongation of the upper-side layer. As a result, the film stress will be reduced and no influence is exerted onto the to-be-processed object. In other words, in case the to-be-processed object is silicon wafer or interlayer dielectric film, no deflection will occur to them. By the way, if the film density of the lower-side layer falls outside the above-described range, there is a disadvantage in that the stress will not be sufficiently relieved. If, on the other hand, the film density of the upper-side layer falls outside the above-described range, there is a disadvantage in that sufficient film density as a mask cannot be obtained.

As described above, according to this invention, by making in two-layer structure the titanium nitride film that constitutes the hard mask, a large reduction in film stress (or reversal in the film stress direction from tensile stress or compressive stress to the other thereof) becomes possible. In addition, the lower-side layer that is relatively lower in film density is restricted to the film thickness within the range of 5 to 50% of the total film thickness of the hard mask. Furthermore, the upper-side layer that is relatively higher in film density is formed to the remaining film thickness, the film density as an entire titanium nitride film can be made to one that is capable of demonstrating etching resistance.

Moreover, in order to solve the above-described problems, the method of manufacturing the hard mask according to this invention comprises: a first step including: evacuating a vacuum processing chamber in which a target made of titanium and the to-be-processed object are disposed; introducing rare gas and nitrogen gas such that the vacuum processing chamber attains a pressure in a range of 0.5 to 30 Pa; applying to the target electric power to form a plasma atmosphere inside the vacuum processing chamber so as to sputter the target, thereby depositing the lower-side layer by reactive sputtering on the surface of the to-be-processed object; and a second step including: evacuating a vacuum processing chamber in which the target made of titanium and the to-be-processed object having deposited thereon the lower-side layer are disposed; introducing rare gas and nitrogen gas such that the vacuum processing chamber attains a pressure in a range of 0.02 to 0.9 time the pressure during the first step; applying to the target electric power equivalent to or above that during the first step to form a plasma atmosphere inside the vacuum processing chamber so as to sputter the target, thereby depositing the upper-side layer by reactive sputtering on the surface of the lower-side layer.

According to this method, it is possible to form, with good mass-productivity, the hard mask that has the film density capable of demonstrating etching resistance but that is constituted by a titanium nitride film of two-layer structure with a low film stress. If the pressure (total pressure) in the first step falls outside the above-described range, there is a disadvantage in that the stress cannot be sufficiently relieved and, if the pressure (total pressure) in the second step falls outside the above-described range, there is a disadvantage in that a sufficient film density as a mask cannot be obtained.

Preferably, the electric power to be applied to the target per unit area in the first step is set to be 0.5 to 5.0 W/cm². Rare gas and nitrogen gas are introduced in the second step so as to attain a pressure equivalent to or below that in the first step, and the electric power to be applied to the target is set to be 1.1 to 4.0 times that in the first step. If the electric power to be applied in the first step is below 0.5 W/cm², there is a disadvantage in that the mass-productivity cannot be obtained. If the electric power in question is above 5.0 W/cm², there is a disadvantage in that the stress cannot be relieved sufficiently. In order to improve the mass-productivity, preferably, the first step and the second step are performed in succession within the same vacuum processing chamber.

### BRIEF DESCRIPTION OF THE DRAWINGS

FIG. 1 is a schematic sectional view of a hard mask according to this invention.

FIG. 2 is a schematic view to explain an example of arrangement of a sputtering apparatus which is used in manufacturing the hard mask according to this invention.

FIG. 3 is a graph showing the relationship between the film stress and film density of a titanium nitride film.

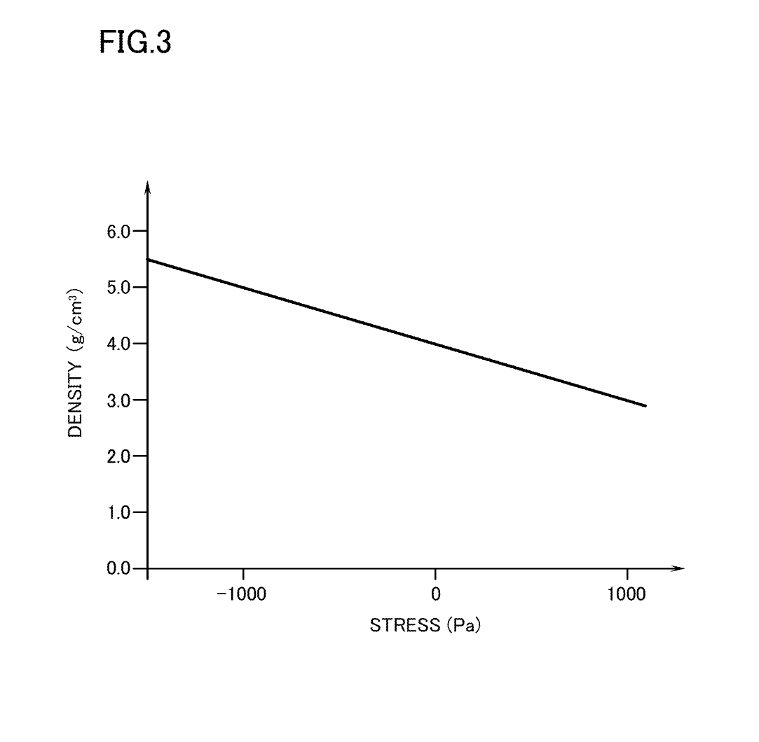

### MODES FOR CARRYING OUT THE INVENTION

With reference to the drawings, explanation will now be made of an embodiment of a hard mask and a method of manufacturing the hard mask by citing an example in which an object to be processed (also referred to as “to-be-processed object”) is silicon wafer (hereinafter referred to as “substrate W”) and in which a hard mask is formed on this silicon substrate.

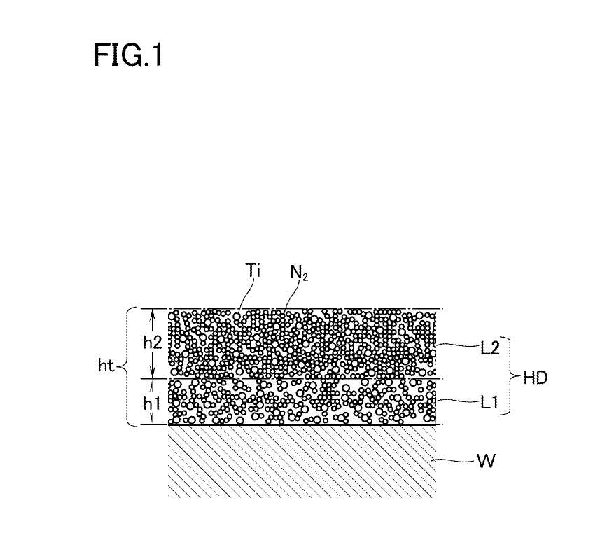

With reference to FIG. 1, reference alphabets HD denote a hard mask that is formed on the surface of the substrate W. As will be described in detail hereinafter, the hard mask HD is formed by successively laminating, in the same vacuum processing chamber, titanium nitride films L1, L2 that are deposited by reactive sputtering into a two-layer structure. The lower-side layer (i.e., the layer on the lower side) L1 has a film thickness h1 within a range of 5 to 50% of the total film thickness ht of the hard mask HD, and has a film density within a range of 3.5 to 4.7 g/cm³. In this case, the film thickness ht of the hard mask HD is appropriately selected depending on the etching conditions at the time of etching the to-be-processed object in the etching process, for example, after the hard mask HD has been formed on the surface of the to-be-processed object in the form of a silicon wafer or an interlayer dielectric film to thereby restrict the range of processing to the to-be-processed object. The upper-side layer L2 has the remaining film thickness h2 with a film density within a range of 4.8 to 5.3 g/cm³. By the way, if the film density of the lower-side layer L1 is outside the above-described range, there are disadvantages in that the stress will not be relieved sufficiently and that, on the other hand, if the film density of the upper-side layer L2 falls outside the above-described range, sufficient film density as a mask cannot be obtained. An explanation will now be made of a method of manufacturing a hard mask HD according to this embodiment.

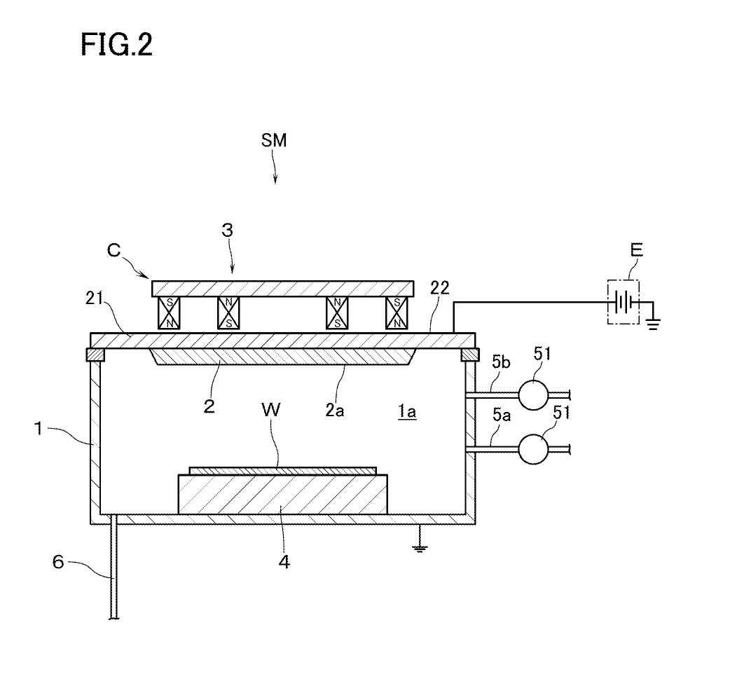

FIG. 2 shows an example of a sputtering apparatus SM which is capable of performing the manufacturing method of the hard mask HD according to this embodiment. The sputtering apparatus SM is of magnetron type and is provided with a vacuum chamber 1 which defines a vacuum processing chamber 1a. On the ceiling portion of the vacuum chamber 1, there is mounted a cathode unit C. In the following descriptions, explanation is made on condition that the direction looking toward the ceiling side of the vacuum chamber 1 is defined as “up or upper” and that the direction looking to the bottom side of the vacuum chamber is defined as “down or lower.”

The cathode unit C is made up of a target 2, and a magnet unit 3 which is disposed above the target 2. The target 2 is made of titanium (e.g., containing titanium and unavoidably included elements, i.e., target consisting essentially of titanium) and is formed by a known method into a circular shape as seen in plan view (i.e., from top) depending on an outline of the substrate W. On an upper surface (i.e., the surface lying opposite to the sputtering surface 2a) of the target 2 there is mounted a backing plate 21 which cools the target 2 during the film deposition by sputtering. The target is attached to the vacuum chamber 1 through an insulating member (not illustrated) with the sputtering surface 2a facing downward. The target 2 has further connected thereto an electrical output from a sputtering power source E such as DC power source and the like. It is so arranged that, during film deposition, DC electric current (below 30 kW) having a negative electric potential is applied to the target 2. The magnet unit 3 which is disposed above the target 2 has a known construction in which a magnetic field is generated in the space below the sputtering surface 2a of the target 2 and in which the electrons and the like ionized below the sputtering surface 2a at the time of sputtering are captured to thereby efficiently ionize the sputtered particles that have been scattered off from the target 2. Therefore, its detailed explanation is omitted here.

At the bottom portion of the vacuum chamber 1 there is disposed a stage 4 in a manner to lie opposite to the sputtering surface 2a of the target 2, and the substrate W is held in position with the film deposition surface lying on the upper side. In this case the distance between the target 2 and the substrate W is set to a range of 45 to 100 mm taking into consideration the mass-productivity, scattering frequency, and the like. The side wall of the vacuum chamber 1 has connected thereto: a first gas pipe 5a for introducing a sputtering gas which is a rare gas such as argon and the like; and a second gas pipe 5b for introducing a reactant gas which is nitrogen gas. The first and second gas pipes 5a, 5b have interposed in each of the pipes a mass flow controller 51, 51 and are in communication with gas sources (not illustrated). According to this arrangement, the flow-controlled sputtering gas and the reactant gas can be introduced into the vacuum processing chamber 1a that is evacuated by the evacuating means (to be described hereinafter) at a constant evacuation speed. It is thus so arranged that, during film deposition, the pressure (total pressure) in the vacuum processing chamber 1a is held substantially constant.

The bottom portion of the vacuum chamber 1 has connected thereto an evacuating pipe 6 which is in communication with an evacuating apparatus (not illustrated) made up of a turbo molecular pump, rotary pump, and the like. Although not particularly illustrated, the above-described sputtering apparatus SM has a known control means which is provided with a microcomputer, sequencer, and the like. It is thus so arranged that the control means performs an overall control over the operation of the above-described electric power supply E, the operation of the mass flow controllers 51, 51, the operation of the evacuating apparatus, and the like. Explanation will now be made in concrete of the method of manufacturing a hard mask HD using the sputtering apparatus SM.

First, after having set in position a substrate W on the stage 4 inside the vacuum chamber 1 in which a target 2 made of titanium has been mounted, the evacuating means is operated to evacuate the inside of the vacuum processing chamber 1a to a predetermined vacuum degree (e.g., 10⁻⁵ Pa). Once the inside of the vacuum processing chamber 1a has reached the predetermined pressure, the mass flow controllers 51, 51 are respectively controlled to thereby introduce argon gas and nitrogen gas in a predetermined flow volume. At this time the flow volumes of argon gas and nitrogen gas are controlled so that the vacuum processing chamber 1a reaches a pressure (total pressure) in the range of 0.5 to 30.0 Pa. If the pressure inside the vacuum processing chamber 1a falls outside the above-described range, there is a disadvantage in that the stress will not be relieved sufficiently. In addition, in case a lower-stress film is to be obtained at a constant pressure, the flow ratio between argon gas and nitrogen gas may be set so as to be equivalent to each other or such that the flow volume of argon gas becomes larger by a range of 1.1 to 1.5 times that of nitrogen gas. By making the flow volume of argon gas larger by the above-described range, larger amount of titan elements will be contained per unit volume, whereby the film stress can be made smaller.

In addition thereto, the target 2 is applied with DC power having a predetermined negative electric potential from the sputtering power supply E to thereby form a plasma atmosphere inside the vacuum chamber 2. According to this arrangement, by means of reactive sputtering, a titanium nitride film on the lower-side layer L1 will be deposited on the surface of the substrate W (first step). In this case, the sputtering time is set such that the titanium nitride film thickness h1 corresponds to a range of 5 to 50% of the total film thickness ht of the hard mask HD. If the film thickness h1 falls outside the range of 5 to 50% of the total film thickness ht of the hard mask HD, the film stress cannot effectively be minimized. Further, the electric power to be applied to the target 2 per unit area is made to be 0.5 to 5.0 W/cm².

Next, when the film deposition of the lower-side layer L1 has been finished, the mass flow controllers 51, 51 are respectively controlled so as to reduce the flow volume of argon gas and nitrogen gas respectively such that the pressure (total pressure) in the vacuum processing chamber 1a attains 0.02 to 0.9 time the total pressure during the first step. This operation is performed in succession from the completion of film deposition of the lower-side layer L1. Alternatively, after the electric power being applied to the target 2 is stopped and also the introduction of the gases is stopped, this operation may be performed after the vacuum processing chamber 1a has been evacuated to the predetermined pressure. If the pressure in the second step is outside the above-described range, there is a disadvantage in that a sufficient film density as a mask cannot be obtained. In combination with the above, the output of the electric power supply E is adjusted so that the electric power to be applied to the target 2 per unit area becomes equivalent to, or above, the electric power applied as set in the first step. In this case, if the applied electric power is below that at the first step, there is a disadvantage in that a sufficient film density as a mask cannot be obtained. According to this arrangement, due to the reactive sputtering, titanium nitride film as the upper-side layer L2 is formed on the surface of the lower-side layer L1 (second step). In this case, the sputtering time is set such that the film thickness h2 becomes the one that reaches the total film thickness ht of the hard mask HD. Although not explained by particularly illustrating, after the titanium nitride film of two-layer structure has been formed, this titanium nitride film is locally etched and patterned depending on the range of processing to be restricted. Since known steps such as lithography steps, and the like can be used for the above-described purpose, detailed explanation thereof will be omitted here.

On the other hand, the hard mask HD may be manufactured in the following manner. In other words, in a similar manner as above, the flow volumes of argon gas and nitrogen gas are controlled such that the vacuum processing chamber 1a attains a pressure (total pressure) within a range of 0.5 to 30.0 Pa. Electric power is applied by the sputtering power supply E to the target 2 so as to attain 0.5 to 5.0 W/cm² to thereby form a plasma atmosphere inside the vacuum chamber 2. According to this arrangement, due to the reactive sputtering, a titanium nitride film of the lower-side layer L1 will be deposited on the surface of the substrate W (first step). In this case, the sputtering time is set so as to attain a film thickness h1 within a range of 5 to 50% of the total film thickness ht of the hard mask HD. If the film thickness h1 falls outside the range of 5 to 50% of the total film thickness ht of the hard mask HD, the film stress cannot effectively be minimized.

Next, when the film deposition of the lower-side layer L1 has been finished, the mass flow controllers 51, 51 are respectively controlled so as to adjust the flow volumes of argon gas and nitrogen gas such that the pressure (total pressure) in the vacuum processing chamber 1a becomes equal to or below the total pressure at the time of the first process. This operation is performed in succession to the completion of film deposition of the lower-side layer L1. Alternatively, after the applying of the electric power to the target 2 is stopped and the introduction of the gases is stopped, this operation may be performed after the vacuum processing chamber 1a has been evacuated to the predetermined pressure. In combination with the above, the output of the sputtering power supply E is changed so that the electric power to be applied to the target 2 per unit area becomes 1.1 to 4.0 times that of the first step. If the electric power to be applied is below 1.1 times that of the first step, there is a disadvantage in that sufficient film density cannot be obtained as a mask. If the electric power to be applied exceeds 4.0 times that of the first step, there is a disadvantage in that the stress cannot be relieved enough. According to this arrangement, due to the reactive sputtering, a titanium nitride film of the upper-side layer L2 is deposited on the surface of the lower-side layer L1 (second step). In this case, the sputtering time is set such that the film thickness h2 becomes thick enough to reach the total film thickness ht of the hard mask HD.

According to the above-described embodiment, it is possible to form with good mass-productivity a hard mask HD that has the mask density to demonstrate etching resistance but that is constituted by two-layer structure of titanium nitride films L1, L2 which are low in film stress. In concrete, the substrate W is first provided with the lower-side layer L1 which is made up of a titanium nitride having a film density within a range of 3.5 to 4.7 g/cm³. As a result, due to the fact that titanium atoms and nitrogen atoms are present at interatomic distances that are relatively stable to the lower-side layer L1, the film stress becomes closer to zero. Then, on the surface of this lower-side layer L1 there is provided an upper-side layer L2 having a film density in the range of 4.8 to 5.3 g/cm³. The upper-side layer L2 has narrow interatomic distances of titanium atoms and nitrogen atoms, and the film stress is high. However, because the upper-side layer is formed on the surface of the lower-side layer L1, the lower-side layer L1 absorbs the elongation of the upper-side layer L2 when the interatomic distances in the upper-side layer L2 are stretched so as to become appropriate. In this case, the film stress will be relieved and there will be inflicted no effect on the substrate W. As a consequence, as regards the film stress, it becomes possible to largely reduce it (or to convert the direction of film stress from the tensile stress or compressive stress to the other thereof). Furthermore, the lower-side layer L1 which is relatively low in film density is restricted in film thickness to a range of 5 to 50% of the total film thickness of the hard mask HD. In addition, the upper-side layer L2 which is relatively high in film density is formed within the remaining film thickness. Therefore, the film density of the titanium nitride films L1, L2 as a whole can be made to demonstrate etching resistance. By the way, the film density can be obtained by using X-ray reflectivity method (XRR) and the film stress can be measured by using a known measuring device.

Then, in order to confirm the above-described effects of this invention, the following experiments were carried out by using the sputtering apparatus SM of the above-described construction. In these experiments a silicon wafer was used as the substrate W. On the surface of this substrate W there was deposited a titanium nitride film of two-layer structure. In this case, a target 2 made of titanium was used. The distance between the target 2 and the substrate W was set to 60 mm. Further, as the sputtering conditions of the first step, the flow volumes of argon gas and nitrogen gas were respectively made to be 200 sccm. The pressure (total pressure) inside the vacuum processing chamber 1a was arranged to be maintained at about 1.4 Pa. In addition, the electric power to be applied to the target 2 was set to 7 kW, and the film deposition time was set to 9 seconds (the film thickness of the lower-side layer L1 was about 5 nm). On the other hand, as the sputtering conditions of the second step, the flow volumes of argon gas and nitrogen gas were respectively set to be 60 sccm. The pressure (total pressure) in the vacuum processing chamber 1a was arranged to be maintained at about 0.4 Pa. Further, the electric power to be applied to the target 2 was set to 7 kW and the film deposition time was set to be 30 seconds (the film thickness of the lower-side layer L1 was about 28 nm). According to this arrangement, it has been confirmed that a titanium nitride film was deposited whose film stress was +10 MPa (tensile stress) and the film density was 4.85 g/cm³.

Descriptions have so far been made of the embodiments of this invention. This invention shall, however, not be limited to the above. In the above-described embodiments, an explanation has been made of an example in which the lower-side layer L1 and the upper-side layer L2 were formed in succession within the same vacuum processing chamber 1a. However, an arrangement may be made that the lower-side layer L1 and the upper-side layer L2 are deposited separately by using different sputtering apparatuses. In addition, in the above-described embodiment, an explanation was made of an example in which a hard mask HD was deposited by using the sputtering apparatus SM. However, as long as a titanium nitride film having the above-described predetermined film density can be deposited, an ion plating apparatus or vapor deposition apparatus, for example, can also be used. Still furthermore, in the above-described embodiment, a silicon wafer was used as an example of the to-be-processed object. This invention may also be applied to an example in which a film is formed on an interlayer dielectric film.

### EXPLANATION OF REFERENCE NUMERALS

| | |
|---|---|
| HD | hard mask L1 lower-side layer L2 upper-side layer |
| SM | sputtering apparatus 1a vacuum processing chamber |
| 2 | Ti target 51, 51 mass flow controller |
| W | silicon wafer (to-be-processed object) |

1. A hard mask provided to restrict a range of processing to a surface of a to-be-processed object when a predetermined processing is performed on the to-be-processed object, the hard mask being constituted by a titanium nitride film,
wherein the titanium nitride film is made into a two-layer structure with: a lower-side layer having a film thickness within a range of 5 to 50% of a total film thickness of the hard mask and also having a film density within a range of 3.5 to 4.7 g/cm³; and an upper-side layer having a film density within a range of 4.8 to 5.3 g/cm³.

2. A method of manufacturing the hard mask as set forth in claim 1, the method comprising:
a first step including: evacuating a vacuum processing chamber in which a target made of titanium and the to-be-processed object are disposed; introducing rare gas and nitrogen gas such that the vacuum processing chamber attains a pressure in a range of 0.5 to 30 Pa; applying to the target electric power to form a plasma atmosphere inside the vacuum processing chamber so as to sputter the target, thereby depositing the lower-side layer, by reactive sputtering, on the surface of the to-be-processed object; and
a second step including: evacuating a vacuum processing chamber in which the target made of titanium and the to-be-processed object having deposited thereon the lower-side layer are disposed; introducing rare gas and nitrogen gas such that the vacuum processing chamber attains a pressure in a range of 0.02 to 0.9 time the pressure during the first step; applying to the target electric power equivalent to or above that during the first step to form a plasma atmosphere inside the vacuum processing chamber so as to sputter the target, thereby depositing the upper-side layer, by reactive sputtering, on the surface of the lower-side layer.

3. The method of manufacturing the hard mask as set forth in claim 2, wherein, in the first step, the electric power to be applied to the target per unit area is set to be 0.5 to 5.0 W/cm², wherein, in the second step, rare gas and nitrogen gas are introduced so as to attain a pressure equivalent to or below that in the first step, and wherein the electric power to be applied to the target is set to be 1.1 to 4.0 times that in the first step.

4. The method of manufacturing the hard mask as set forth in claim 2, wherein the first step and the second step are performed in succession within an identical vacuum processing chamber.

5. The method of manufacturing the hard mask as set forth in claim 3, wherein the first step and the second step are performed in succession within an identical vacuum processing chamber.
